(19) United States
(12) Patent Application Publication
(10) Pub. No.: US 2007/0215957 A1
(43) Pub. Date: Sep. 20, 2007

(54) GATE DIELECTRIC STRUCTURE AND AN ORGANIC THIN FILM TRANSISTOR BASED THEREON

(76) Inventors: Fang-Chung Chen, Taichung City (TW); Chiao-Shun Chuang, Kaohsiung City (TW); Yung-Sheng Lin, Jhonghe City (TW)

Correspondence Address: SINORICA, LLC, 528 FALLSGROVE DRIVE, ROCKVILLE, MD, 20850, US

(21) Appl. No.: 11/459,409

(22) Filed: Jul. 24, 2006

(30) Foreign Application Priority Data
Mar. 17, 2006 (TW) 95109191

(51) Int. Cl. H01L 29/94; H01L 29/76; H01L 31/00

(52) U.S. Cl. 257/411

(57) ABSTRACT

A gate dielectric structure and an organic thin film transistor based thereon, wherein the gate dielectric structure comprises: an organic-inorganic composite layer and an organic insulation layer, and the gate dielectric structure is applied to an organic thin film transistor. As the organic-inorganic composite layer of the gate dielectric structure has an organic insulation matrix blended with inorganic surface-modified particles, it can achieve a high dielectric constant. Further, as the organic insulation layer can modify the surface of the organic-inorganic composite layer, not only the leakage current is reduced, but also the crystalline structure of the organic semiconductor layer becomes more orderly. Thus, the carrier mobility is raised, the current output of the element is increased, and the performance of the element is also greatly enhanced.

### BACKGROUND OF THE INVENTION

1. Field of the Invention

The present invention relates to a high-k dielectric thin film structure, particularly to a high-k gate dielectric structure implemented with an organic-inorganic composite material and an organic thin film transistor based thereon.

2. Description of the Invention

The study of organic semiconductor elements has been a focal research topic in the fields concerned recently. Among them, OTFT (Organic Thin Film Transistor) has begun to be commercialized, and the OTFT-based RFID (Radio Frequency Identification) products have also entered into the stage of trial production. The flexible substrate, display, and electronic paper, which can be realized with OTFT, are also under development. Further, OTFT is advantaged in the simple, low-temperature and low-cost fabrication process. Therefore, the commercial potential thereof is immeasurable.

However, the conventional OTFT needs a pretty high operational voltage because its carrier mobility is very low. Therefore, the OTFT's capability of driving a high-current element, such as OLED, is yet hard to meet industrial requirements. For a transistor, the field-induced current is proportional to the density of field-induced charges and the mobility of carriers. Therefore, the problem of low current output may be overcome by increasing the density of field-induced charges via adopting a high-k dielectric film.

However, the dielectric constant of the conventional organic dielectric film is not high enough (usually only about 2.0˜4.0). When the OTFT gate dielectric layer adopts such a conventional organic dielectric film, the induced charges are also insufficient. In prior arts, nanometric particles are embedded inside an organic dielectric film to increase the dielectric constant thereof. However, the solubility of nanometric particles is not high enough, and thus, the increased dielectric constant value is also limited.

### SUMMARY OF THE INVENTION

The primary objective of the present invention is to provide a gate dielectric structure and an organic thin film transistor based thereon, wherein the gate dielectric structure comprises: an organic-inorganic composite layer, containing surface-modified inorganic particles; and an organic insulation layer, modifying the surface of the organic-inorganic composite layer in order to achieve a high dielectric constant and prevent leakage current. The organic thin film transistor based on the gate dielectric structure of the present invention may have more induced charges; thus, the output current of the element is increased, and the performance of the element is also promoted.

Another objective of the present invention is to provide a gate dielectric structure and an organic thin film transistor based thereon, wherein a high-k gate dielectric structure can be economically fabricated with only a solution coating method and a low-temperature process and without any complicated sputtering technology and high-temperature tempering process. Thus, the fabrication process can be simplified, and the fabrication cost can be reduced.

To achieve the abovementioned objectives, the gate dielectric structure disclosed in the present invention comprises: an organic-inorganic composite layer and an organic insulation layer. The organic-inorganic composite layer has a matrix made of an organic insulation material, and a plurality of inorganic particles is blended inside the matrix. The inorganic particles are surface-modified in order to increase the solubility of the inorganic particles in the matrix made of the organic insulation material. Thereby, the dielectric constant of the organic-inorganic composite layer can be increased. Further, the organic insulation layer can modify the surface of the organic-inorganic composite layer so that the flatness of the organic-inorganic composite layer can be increased, and the leakage current can be prevented.

The gate dielectric structure of the present invention can apply to MOS (Metal Oxide Semiconductor), MIS (Metal Insulator Semiconductor), TFT (Thin Film Transistor), OTFT (Organic Thin Film Transistor), etc. Herein, the application of the gate dielectric structure to OTFT is used to exemplify the present invention. Due to the inorganic particles embedded inside the matrix, the organic-inorganic composite layer has a high dielectric constant; thus, the density of the field-induced charges in OTFT is raised, and the problem of insufficient output current is overcome. Further, the organic insulation layer between the organic-inorganic composite layer and the organic semiconductor layer not only can smooth the surface of the organic-inorganic composite layer and reduce the defect density of the organic-inorganic composite layer so that the leakage current can be decreased, but also can help the organic semiconductor layer to form more orderly crystalline structure and maintain the mobility of carriers.

To enable the objectives, structural characteristics, and functions of the present invention to be more easily understood, the present invention is to be described in detail in cooperation with the attached drawings below.

### BRIEF DESCRIPTION OF THE INVENTION

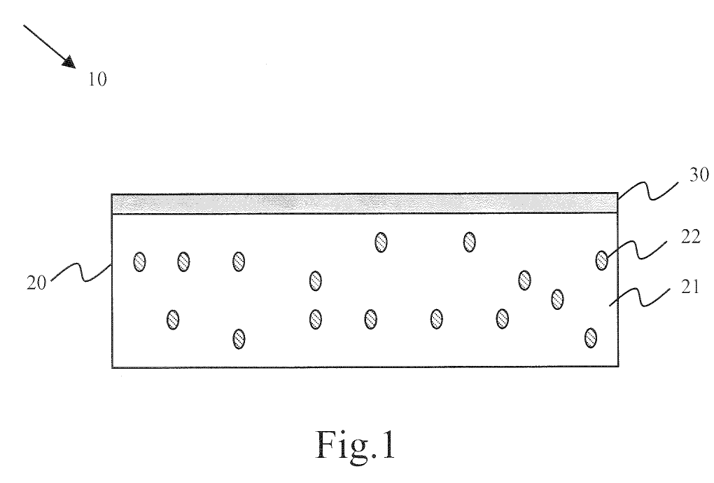

FIG. 1 is a diagram schematically showing the gate dielectric layer of the present invention.

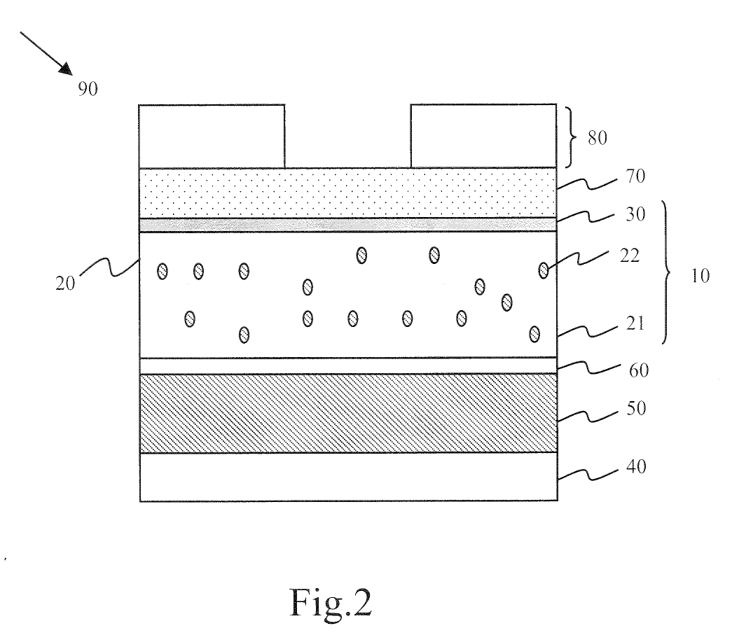

FIG. 2 is a diagram schematically showing the bottom-gate OTFT according to an embodiment of the present invention.

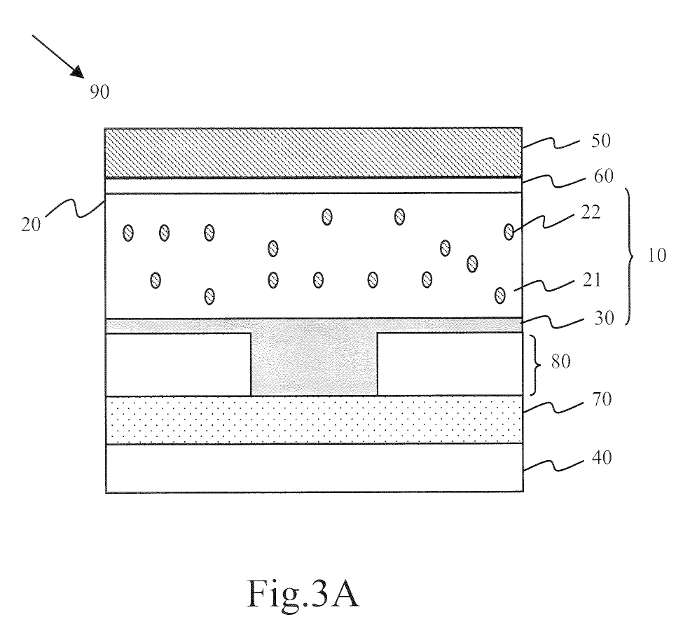

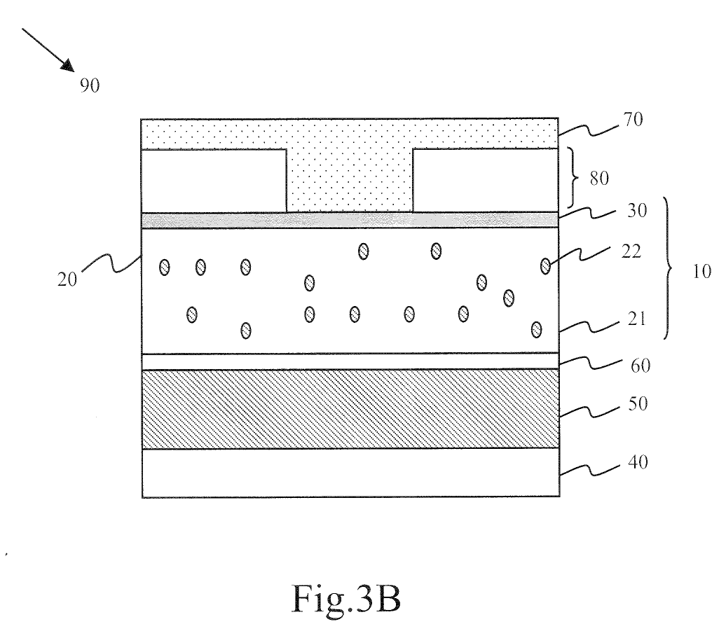

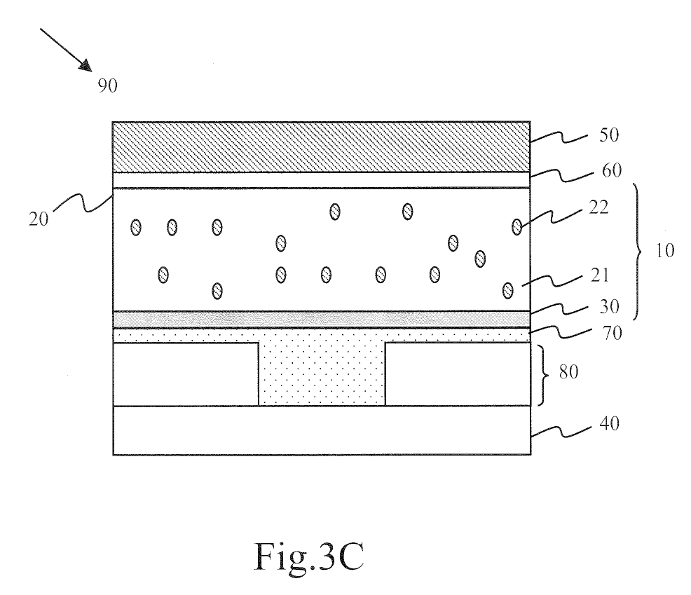

FIG. 3A to FIG. 3C are diagrams respectively showing the coplanar TFT, the inverted coplanar TFT, and the staggered TFT according to the present invention.

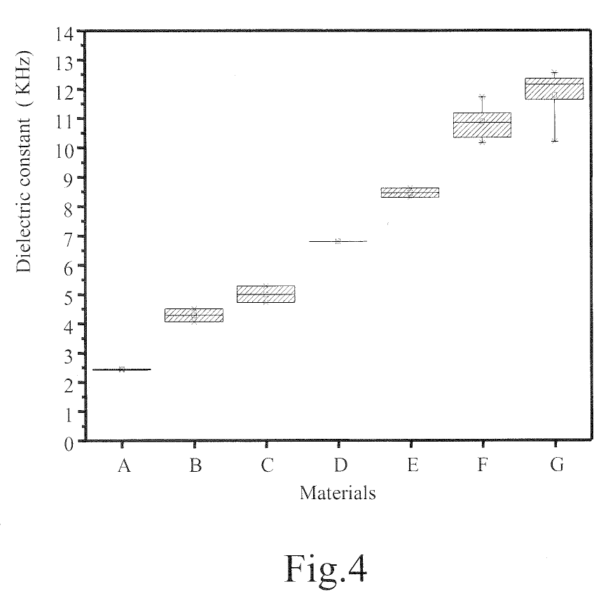

FIG. 4 is a diagram showing the relationship between the dielectric constant of the organic-inorganic composite layer and the concentration of inorganic titanium-dioxide particles according to the present invention.

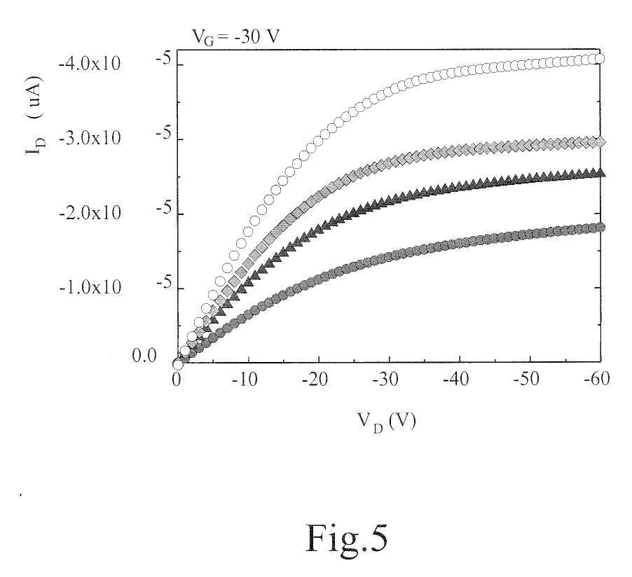

FIG. 5 is a diagram showing the drain current-drain voltage (I_{D}-V_{D}) curves of the OTFT gate dielectric structures with the organic-inorganic composite layers respectively having different concentrations of inorganic titanium-dioxide particles according to the present invention.

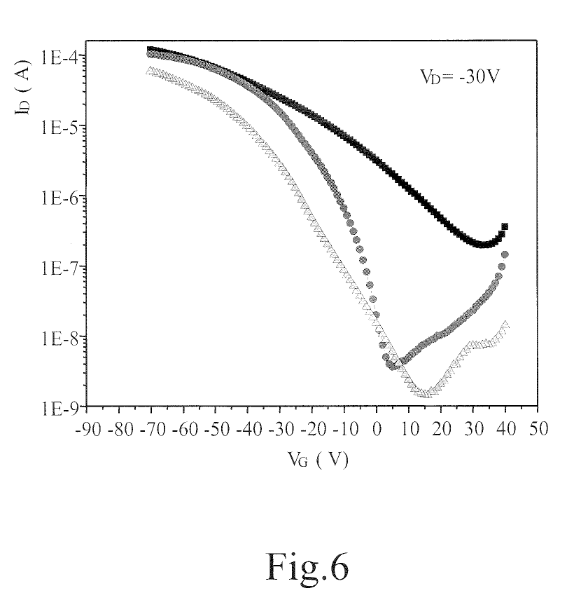

FIG. 6 is a diagram showing the drain current-gate voltage (I_{D}-V_{G}) curves of the OTFT's with the gate dielectric structures respectively having different compositions according to the present invention.

### DETAILED DESCRIPTION OF THE INVENTION

Refer to FIG. 1 a diagram schematically showing the gate dielectric layer disclosed in the present invention. The gate dielectric structure 10 essentially comprises: an organic-inorganic composite layer 20 and an organic insulation layer 30.

In the organic-inorganic composite layer 20, an organic insulation material is used as the matrix 21, and a plurality of high-k inorganic particles 22 are dispersed inside the matrix 21 in order to increase the dielectric constant of the organic-inorganic composite layer 20. The inorganic particles 22 are very tiny particles fabricated via a chemical reaction or a physical dispersion process, and the surfaces of the inorganic particles 22 are modified so that the inorganic particles 22 can be uniformly distributed inside the organic insulation matrix 21, and the solubility of the inorganic particles 22 in the organic insulation matrix 21 can be increased. Thereby, the dielectric performance of the organic-inorganic composite layer 20 is promoted.

In order to prevent the higher leakage current, which usually accompanies the adoption of a high-k dielectric material, the organic insulation layer 30 is used to modify the surface of the organic-inorganic composite layer 20 so that the surface of the organic-inorganic composite layer 20 can be smoothed, and the defect density of the organic-inorganic composite layer 20 can be obviously reduced. Thereby, the leakage current is inhibited.

A simple and low-cost solution coating method can be used to fabricate the gate dielectric structure 10, and the complicated sputtering method is unnecessary therein. A fabrication method of the organic-inorganic composite layer 20 is to be described below. Firstly, the powder of titanium dioxide (TiO₂) particles with the size of about 50 nm is added into the PGMEA (propylene glycol monomethyl ether acetate) solution containing PVP (poly-4-vinylphenol) and poly (melamine-co-formaldehyde) methlated, and the mixture is forcefully agitated to form a uniformly dispersed solution. Such a solution is used to form a thin and uniform film with a spinning coating method, and the thin film is pre-baked at 120° C. for 5 minutes, and then baked at 200° C. for 20 minutes to obtain a fine high-permittivity organic-inorganic composite layer 20.

In order to provide a more detailed exemplification of the present invention, below will describe the application of the gate dielectric structure to the bottom-gate inverted-staggered organic thin film transistor (OTFT). Refer to FIG. 2 a diagram schematically showing the bottom-gate OTFT according to an embodiment of the present invention.

According to this embodiment, the fabrication of the OTFT 90 is described below. Firstly, an ITO (Indium Tin Oxide) layer is grown on a substrate 40, and the ITO layer functions as a gate layer 50. An organic film is deposited on the gate layer 50 and functions as organic modifying layer 60 of the gate layer 50. Next, an organic-inorganic composite layer 20 is formed on the organic modifying layer 60 with a spinning coating method. The organic-inorganic composite layer 20 adopts an organic insulation material as the matrix 21, and a plurality of titanium dioxide particles 22, which are chemically surface-modified, are uniformly distributed inside the matrix 21. Next, an organic insulation layer 30 is deposited on the surface of the organic-inorganic composite layer 20; then, the organic insulation layer 30 and the organic-inorganic composite layer 20 jointly form a gate dielectric layer 10. Next, an organic semiconductor layer 70 is deposited on the organic insulation layer 30. Finally, a source and drain 80 is formed on the organic semiconductor layer 70, and thus, a simple bottom-gate OTFT 90 is completed.

In this embodiment, the substrate 40 may be a glass substrate, a polymeric plastic substrate, such as a PET (polyethylene teraphthalate) substrate or a PC (polycarbonate) substrate, or another electronic-circuit substrate, such as a silicon substrate.

The gate layer 50 is not limited to an ITO transparent layer or an IZO (Indium Zinc Oxide) transparent layer but may also be a thin film of aluminum, titanium, nickel, copper, gold or chromium, or a thin film of highly-doped silicon, or a thin film of a conductive polymeric material, such as polyaniline or PEDOT:PSS (3,4-polyethylenedioxythiophene-polystyrenesulfonate).

The organic insulation material of the organic-inorganic composite layer 20 may be a common polymeric insulation material, such as polyimide, polyamide, parylene, PVP (poly(vinylphenol)), or PMMA (polymethylmethacrylate).

In this embodiment, the inorganic particles 22 are titanium dioxide (TiO₂) particles and have a dielectric constant of 112. In fact, the inorganic particles 22 may be common high-k dielectric particles with a dielectric constant within from 20 to 500, such as barium titanate (BaTiO₃) particles, zirconium dioxide (ZrO₂) particles, or tantalum trioxide (Ta₂O₃) particles. The material used in chemical surface modification may be an organosilane, such as OTS (octadecyltrichlorosilane), butyltrichlorosilane, or phenethyltrichlorosilane. However, the surface modifier is not limited to the abovementioned organosilanes but may be any appropriate material, which can increase the solubility of the inorganic particles 22.

The organic insulation layer 30 is used to modify the surface of the organic-inorganic composite layer 20 and may be made of a common polymeric insulation material, such as polyimide, polyamide, parylene poly-α-methylstryene, PVP (poly(vinylphenol), or PMMA (polymethylmethacrylate). The organic insulation layer 30 may also be a layer made of a plurality of types of molecules, such as a self-assemble monolayer.

The organic modifying layer 60 may be made of a common conductive polymer, such as polyaniline or PEDOT:PSS (3,4-polyethylenedioxythiophene-polystyrenesulfonate).

The organic semiconductor layer 70 may be made of a common organic semiconductor molecule or a common semiconductor polymer. The organic semiconductor molecule may be selected from the group consisting of tetracene, pentacene, phthalocyanine, and C60. The semiconductor polymer may be selected from the group consisting of polythiophene, polyfluorene, polyphenylenevinylene, and the derivatives of the abovementioned polymers, such as poly(3-octyl)thiophene, poly(dioctylfluorene), and poly[2-methoxy-5-(2′-ethyl-hexyloxy)-1,4-phenylene vinylene]. The semiconductor polymer may also be an oligomer, such as α-sexithiophene.

The source and drain 80 may be made of a transparent oxide, such as ITO (Indium Tin Oxide) or IZO (Indium Zinc Oxide), or a metallic film, such as the film of aluminum, titanium, nickel, copper, gold or chromium, or a conductive polymer, such as polyaniline or PEDOT:PSS (3,4-polyethylenedioxythiophene-polystyrenesulfonate).

This embodiment also applies to the bottom-contact type TFT, the top-contact type TFT, and the top-gate TFT. Refer to from FIG. 3A to FIG. 3C diagrams respectively showing the coplanar TFT, the inverted coplanar TFT, and the staggered TFT.

The efficacies of the present invention have been verified with some experiments to be described below.

Refer to FIG. 4 a diagram showing the relationship between the dielectric constant of the organic-inorganic composite layer and the concentration of inorganic titanium dioxide particles, wherein A in the horizontal axis denotes the case of using only an organic insulation layer, and B, C, D, E, F respectively denote the cases of the organic-inorganic composite layers having 0 wt %, 1 wt %, 5 wt %, 10 wt %, and 15 wt % inorganic particles, G denotes the case of the organic-inorganic composite layer having 15 wt % inorganic particles plus the organic insulation layer. The results of the experiments show that the dielectric constant of the organic-inorganic composite layer having inorganic titanium dioxide particles increases with the concentrations of the inorganic particles. Thus, the addition of high-k dielectric inorganic particles can indeed promote the dielectric constant of the organic-inorganic composite layer.

Refer to FIG. 5 a diagram showing the drain current-drain voltage (I_{D}-V_{D}) curves of the OTFT gate dielectric structures respectively with the organic-inorganic composite layers having 0 wt %, 5 wt %, 10 wt %, and 15 wt % inorganic particles from bottom to top. The results of the experiments show that the output current increases with the concentrations of the inorganic particles. The gate dielectric structure implemented with the organic-inorganic composite layer can really increase the current and voltage output.

Refer to FIG. 6 a diagram showing the drain current-gate voltage (I_{D}-V_{G}) curves respectively of the OTFT's with the gate dielectric structures having different compositions, wherein from top to bottom, those three curves respectively correspond to the organic-inorganic composite layer having 15 wt % inorganic particles, the organic-inorganic composite layer having 15 wt % inorganic particles plus the organic insulation layer, and the organic-inorganic composite layer having 1 wt % inorganic particles. The results of the experiments show that the leakage current increases with the concentration of the inorganic particles. Thus, it is rational to deduce that a higher concentration of inorganic particles may induce some structural defects. The surface roughness of the organic-inorganic composite layer grows with the concentration of inorganic particles, and the higher the roughness, the grater the leakage current. After the organic insulation layer has modified the surface of the organic-inorganic composite layer, the leakage current is obviously reduced, and the on/off ratio is also greatly promoted. Further, the organic insulation layer can help the organic semiconductor layer to form more orderly crystalline structure so that the carrier mobility and the switching performance of the element will be promoted.

The organic insulation layer can smooth the surface of the organic-inorganic composite layer and help the organic semiconductor layer to form more orderly crystalline structure so that the carrier mobility will be promoted. Refer to Table.1 for the dielectric constant and other characteristics of the OTFT's with different gate dielectric structures, wherein the gate dielectric structures include: those respectively having the organic-inorganic composite layers with different concentrations of inorganic titanium dioxide particles, and those having the organic-inorganic composite layer plus the organic insulation layer.

TABLE 1

| | | Dielec- | μₐₜ | | Surface | |
|---|---|---|---|---|---|---|
| | TiO₂ | tric | (cm²/Vs) | | rough- | |
| TiO₂ | volume | con- | 1̅6̅0̅ μ̅m̅ +̅/̅−̅ | | ness | On/Off |
| wt % | fraction | stant | 5% | Vt (V) | (nm) | ratio |
| 0% | 0 | 4.3 | 0.42 | −5.2 | 0.30 | 5 × 10⁴ |
| 1% | 2.41 | 4.8 | 0.39 | −14.4 | 9.76 | 4 × 10⁴ |
| 5% | 11.01 | 6.7 | 0.42 | −10.9 | 16.19 | 9 × 10³ |
| 10% | 19.84 | 8.5 | 0.34 | −3.3 | 26.99 | 6 × 10³ |
| 15% | 27.07 | 10.8 | 0.32 | +5.9 | 31.43 | 1 × 10³ |
| 15%/ | 27.07 | 11.6 | 0.41 | −3.0 | 13.30 | 3 × 10⁴ |
| Organic | | | | | | |
| insulation | | | | | | |
| layer | | | | | | |

It can be found from the table that the current output by the element is considerably raised. Thus, it is proved that the gate dielectric structure comprising the organic-inorganic composite layer and the organic insulation layer of the present invention can really promote the performance of the element.

Besides, the gate dielectric structure of the present invention can apply to MOS (Metal Oxide Semiconductor), MIS (Metal Insulator Semiconductor), TFT (Thin Film Transistor), OTFT (Organic Thin Film Transistor), etc. The gate dielectric structure of the present invention can promote the performance of the element via increasing the dielectric constant and preventing the leakage current.

The present invention has been clarified with the embodiments described above; however, it is not intended to limit the scope of the present invention. Any equivalent modification and variation according to the spirit of the present invention is to be also included within the scope of the present invention, which depends on the claims stated below.

What is claimed is:

1. A gate dielectric structure, comprising:
an organic-inorganic composite layer, having a matrix made of an organic insulation material with aid matrix containing a plurality of inorganic particles with a modified surface; and
an organic insulation layer, disposed on said organic-inorganic composite layer, and modifying the surface of said organic-inorganic composite layer.

2. The gate dielectric structure of claim 1, wherein said organic insulation material is selected from the group consisting of polyimide, polyamide, parylene, PVP (poly(vinylphenol)), and PMMA (polymethylmethacrylate).

3. The gate dielectric structure of claim 1, wherein said inorganic particles are selected from the group consisting of titanium dioxide particle (TiO₂), barium titanate (BaTiO₃) particle, zirconium dioxide (ZrO₂) particle, and tantalum trioxide (Ta₂O₃) particle.

4. The gate dielectric structure of claim 1, wherein said inorganic particles are chemically surface-modified with an organosilane.

5. The gate dielectric structure of claim 4, wherein said organosilane is selected from the group consisting of OTS (octadecyltrichlorosilane), butyltrichlorosilane, and phenethyltrichlorosilane.

6. The gate dielectric structure of claim 1, wherein the material of said organic insulation layer is selected from the group consisting of polyimide, polyamide, parylene, PVP (poly(vinylphenol)), PMMA (polymethylmethacrylate), and poly-α-methylstryene.

7. The gate dielectric structure of claim 1, wherein said organic insulation layer is a self-assemble monolayer.

8. The gate dielectric structure of claim 1, wherein said inorganic particles have a dielectric constant within from 20 to 500.

9. The gate dielectric structure of claim 1, wherein said organic-inorganic composite layer is fabricated with a solution coating method.

10. An organic thin film transistor, comprising:
a source-drain layer, further comprising a source, a drain and a channel with said source and said drain respectively disposed at two sides of said channel;
a gate layer, disposed vertically to said channel of said source and said drain;
a gate dielectric structure, further comprising:
an organic-inorganic composite layer, separating said gate layer and said source-drain layer, having a matrix made of an organic insulation material with said matrix containing a plurality of inorganic particles with a modified surface; and
an organic insulation layer, disposed on the surface of said organic-inorganic composite layer;
an organic semiconductor layer, connecting with said source-drain layer and said organic insulation layer; and
a substrate, accommodating said source-drain layer, said gate layer, said gate dielectric structure, and said semiconductor layer.

11. The organic thin film transistor of claim 10, wherein said gate layer is disposed on said substrate; said gate dielectric structure is accommodated by said substrate and overlays said gate layer; said source-drain layer is accommodated by said substrate and overlays said gate dielectric structure; and said organic semiconductor layer is disposed on said source-drain layer.

12. The organic thin film transistor of claim 10, wherein said gate layer is disposed on said substrate; said gate dielectric structure is accommodated by said substrate and overlays said gate layer; said organic semiconductor layer is accommodated by said substrate and overlays said gate dielectric structure; and said source-drain layer is disposed on said organic semiconductor layer.

13. The organic thin film transistor of claim 10, wherein said organic semiconductor layer is disposed on said substrate; said source-drain layer is accommodated by said substrate and overlays said organic semiconductor layer; said gate dielectric structure is accommodated by said substrate and overlays said source-drain layer; and said gate layer is disposed on said gate dielectric structure.

14. The organic thin film transistor of claim 10, wherein said source-drain layer is disposed on said substrate; said organic semiconductor layer is accommodated by said substrate and overlays said source-drain layer; said gate dielectric structure is accommodated by said substrate and overlays said organic semiconductor layer; and said gate layer is disposed on said gate dielectric structure.

15. The organic thin film transistor of claim 10, wherein said source-drain layer is made of a transparent oxide, a metal or a conductive polymer.

16. The organic thin film transistor of claim 15, wherein said transparent oxide is selected from the group consisting of ITO (Indium Tin Oxide) and IZO (Indium Zinc Oxide).

17. The organic thin film transistor of claim 15, wherein said metal is selected from the group consisting of aluminum, titanium, nickel, copper, gold and chromium.

18. The organic thin film transistor of claim 15, wherein said conductive polymer is selected from the group consisting of polyaniline and PEDOT:PSS (3,4-polyethylenedioxythiophene-polystyrenesulfonate).

19. The organic thin film transistor of claim 10, wherein said gate layer is made of a transparent oxide, a metal, a highly-doped silicon, or a conductive polymer.

20. The organic thin film transistor of claim 19, wherein said transparent oxide is selected from the group consisting of ITO (Indium Tin Oxide) and IZO (Indium Zinc Oxide).

21. The organic thin film transistor of claim 19, wherein said metal is selected from the group consisting of aluminum, titanium, nickel, copper, gold and chromium.

22. The organic thin film transistor of claim 19, wherein said conductive polymer is selected from the group consisting of polyaniline and PEDOT:PSS (3,4-polyethylenedioxythiophene-polystyrenesulfonate).

23. The organic thin film transistor of claim 10, wherein said organic insulation material is selected from the group consisting of polyimide, polyamide, parylene, PVP (poly(vinylphenol)), and PMMA (polymethylmethacrylate).

24. The organic thin film transistor of claim 10, wherein said inorganic particle is selected from the group consisting of titanium-dioxide particle (TiO₂), barium titanate (BaTiO₃) particle, zirconium dioxide (ZrO₂) particle, and tantalum trioxide (Ta₂O₃) particle.

25. The organic thin film transistor of claim 10, wherein said inorganic particles are chemically surface-modified with an organosilane.

26. The organic thin film transistor of claim 25, wherein said organosilane is selected from the group consisting of OTS (octadecyltrichlorosilane), butyltrichlorosilane, and phenethyltrichlorosilane.

27. The organic thin film transistor of claim 10, wherein the material of said organic insulation layer is selected from the group consisting of polyimide, polyamide, parylene, PVP (poly(vinylphenol)), PMMA (polymethylmethacrylate), and poly-α-methylstryene.

28. The organic thin film transistor of claim 10, wherein said organic insulation layer is a self-assemble monolayer.

29. The organic thin film transistor of claim 10, wherein said inorganic particles have a dielectric constant within from 20 to 500.

30. The organic thin film transistor of claim 10, wherein said organic semiconductor layer is made of an organic semiconductor molecule or a semiconductor polymer.

31. The organic thin film transistor of claim 30, wherein said organic semiconductor molecule is selected from the group consisting of tetracene, pentacene, phthalocyanine, and C60.

32. The organic thin film transistor of claim 30, wherein said semiconductor polymer is selected from the group consisting of polythiophene, polyfluorene, polyphenylenevinylene, and the derivatives of the abovementioned polymers.

33. The organic thin film transistor of claim 32, wherein said derivative is selected from the group consisting of poly(3-octyl)thiophene, poly(dioctylfluorene), and poly[2-methoxy-5-(2′-ethyl-hexyloxy)-1,4-phenylene vinylene].

34. The organic thin film transistor of claim 30, wherein said semiconductor polymer is α-sexithiophene.

35. The organic thin film transistor of claim 10, wherein the material of said substrate is selected from the group consisting of glass (SiO₂), polymeric plastic, and silicon substrate.

36. The organic thin film transistor of claim 35, wherein said polymeric plastic is selected from the group consisting of PET (polyethylene teraphthalate) and PC (polycarbonate).

37. The organic thin film transistor of claim 10, further comprising an organic modifying layer, which is disposed between said gate layer and said organic-inorganic composite layer and used to modify a surface of said gate layer so that performance of said organic thin film transistor can be promoted.

38. The organic thin film transistor of claim 37, wherein said organic modifying layer is made of PEDOT:PSS (3,4-polyethylenedioxythiophene-polystyrenesulfonate).

39. The organic thin film transistor of claim 10, wherein said organic-inorganic composite layer is fabricated with a solution coating method.
